(19) United States
(12) Patent Application Publication
(10) Pub. No.: US 2006/0281271 A1
(43) Pub. Date: Dec. 14, 2006

(54) Method of forming a semiconductor device having an epitaxial layer and device thereof

(75) Inventors: David E. Brown, Pleasant Valley, NY (US); William George En, Milpitas, CA (US); Thorsten Kammler, Ottendorf-Okrilla (DE); Paul R. Besser, Sunnyvale, CA (US); Scott D. Luning, Poughkeepsie, NY (US)

Correspondence Address: LARSON NEWMAN ABEL POLANSKY & WHITE, LLP, 5914 WEST COURTYARD DRIVE, SUITE 265, AUSTIN, TX, 78730, US

(73) Assignee: Advanced Micro Devices, Inc., Sunnyvale, CA (US)

(21) Appl. No.: 11/150,899

(22) Filed: Jun. 13, 2005

(51) Int. Cl. H01L 21/336

(52) U.S. Cl. 438/303

(57) ABSTRACT

Integration schemes are presented which provide for decoupling the placement of deep source/drain (S/D) implants with respect to a selective epitaxial growth (SEG) raised S/D region, as well as decoupling silicide placement relative to a raised S/D feature. These integration schemes may be combined in multiple ways to permit independent control of the placement of these features for optimizing device performance. The methodology utilizes multiple spacers to decrease current crowding effects in devices due to proximity effects between LDD and deep S/D regions in reduced architecture devices.

### CROSS-REFERENCE TO RELATED APPLICATION(S)

Related subject matter is found in a copending U.S. patent application, having application Ser. No. 10/791,346 (Attorney Docket Number 1458-H1946), filed Mar. 2, 2004, entitled “CONTAMINATION REMOVAL PROCESSES DURING SEMICONDUCTOR MANUFACTURING”, which is hereby incorporated herein by reference in its entirety. Related subject matter is found in a copending U.S. patent application, having application Ser. No. 10/969,769 (Attorney Docket Number 1458-H1962), filed Oct. 20, 2004, entitled “METHOD FOR POST OFFSET SPACER CLEAN FOR IMPROVED SELECTIVE EPITAXY SILICON GROWTH”, which is hereby incorporated herein by reference in its entirety. Related subject matter is found in a copending U.S. patent application, having application Ser. No. 10/969,771 (Attorney Docket Number 1458-H2107), filed Oct. 20, 2004, entitled “METHOD OF CLEANING A SURFACE OF A SEMICONDUCTOR SUBSTRATE”, which is hereby incorporated herein by reference in its entirety. Related subject matter is found in a copending U.S. patent application, having application Ser. No. 10/969,774 (Attorney Docket Number 1458-H1955), filed Oct. 20, 2004, entitled “DEVICE COMPRISING AN EPITAXIAL LAYER AND METHOD THEREOF”, which is hereby incorporated herein by reference in its entirety.

### FIELD OF THE INVENTION

The present disclosure relates generally to a semiconductor device and manufacturing process and more particularly to transistor formation associated with semiconductor devices.

### DESCRIPTION OF THE RELATED ART

Typical semiconductor integration schemes utilize a single spacer, generally a nitride spacer, for defining the location of characteristics and features of the device, such as the deep source/drain (S/D) implants, the suicides, and the raised S/D regions at a single, specific distance, relative to the poly silicon gate edge. The use of single spacers throughout the formation processes in semiconductor device manufacturing is limiting to the design engineer when attempting to make adjustments in defining device characteristics and features such as current crowding, series resistance, overlap capacitance, and junction depth to optimally tune the performance of a device. For example, if the width of a spacer is changes, all of the characteristics and features of a device can change as a result.

Therefore, a method that permits independent control of more characteristics and features of a device, such as deep S/D locations, raised S/D regions, and silicide placement would be useful.

### BRIEF DESCRIPTION OF THE DRAWINGS

The present disclosure may be better understood, and its numerous features and advantages made apparent to those skilled in the art by referencing the accompanying drawings. It will be appreciated that elements illustrated in the figures are not necessarily drawn to scale.

FIGS. 1 through 9 illustrate, in cross section, semiconductor device manufacturing process steps according to various embodiments of the present disclosure;

FIGS. 10 and 11 illustrate cross-sectional views of portions of semiconductor devices manufactured according to at least one embodiment of the present disclosure; and

FIG. 12 is a flow diagram of a method for decoupling raised source/drain, deep source/drain implant, and silicide locations according to at least one embodiment of the present disclosure.

The use of the same reference symbols in different drawings indicates similar or identical items.

### DESCRIPTION OF THE PREFERRED EMBODIMENTS

Integration schemes are presented for decoupling the placement of deep source/drain (S/D) implants with respect to a selective epitaxial growth (SEG) raised S/D region, as well as decoupling silicide placement relative to a raised S/D feature. These integration schemes may be combined in multiple ways to permit independent control of the placement of these processes for optimal device performance.

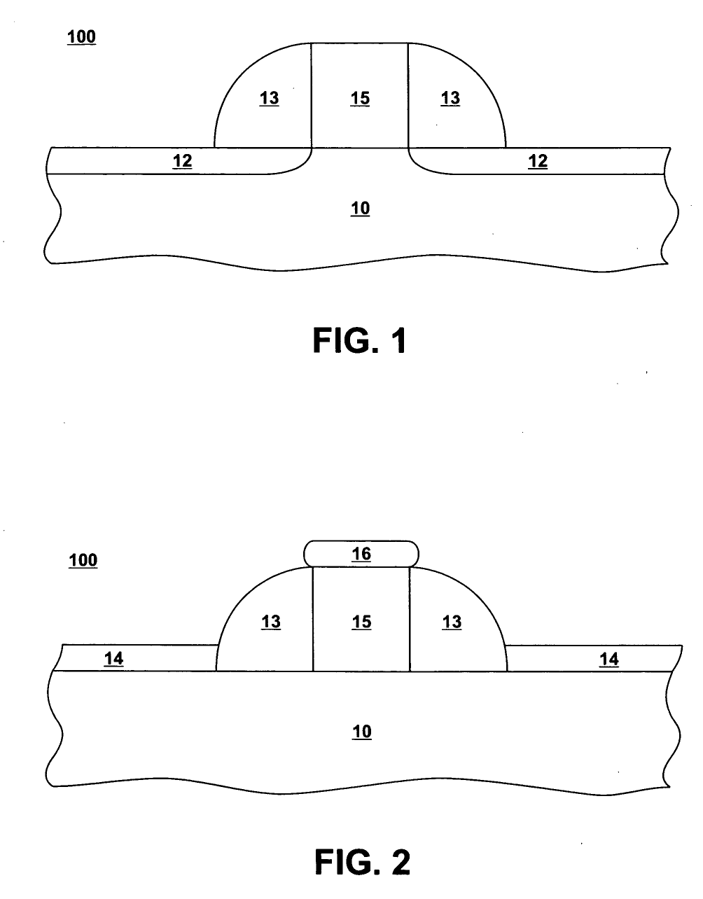

In an embodiment, the present disclosure provides a method for using spacers to independently control the location of a deep source/drain (S/D) implantation and raised S/D silicide locations with respect to the edge of a transistor gate. The method comprises the steps of forming a first sidewall spacer adjacent to a conductive gate, then forming an epitaxial layer overlying the substrate adjacent to the first sidewall spacer. Following this selective epitaxial growth (SEG) process, the first sidewall spacer is removed. A second sidewall spacer is then formed adjacent to the conductive gate and overlying a portion of the epitaxial layer. Deep S/D regions are then formed. These deep S/D regions are offset from the conductive gate structure by an amount defined by the second sidewall spacer. This method is presented with reference to FIGS. 1 through 5.

In another embodiment, a method of manufacturing a semiconductor device utilizing a plurality of spacers to control the location of a deep source/drain (S/D) implantation and raised S/D silicide locations with respect to the edge of a transistor gate is presented. This method comprises forming a first sidewall spacer adjacent to a conductive gate overlying a substrate, then forming a second sidewall spacer overlying the first sidewall spacer and adjacent to the conductive gate. Following the formation of the second sidewall spacer, an epitaxial layer is formed overlying a region of the substrate adjacent to the second sidewall spacer. Deep S/D regions are then formed, and these deep S/D regions are offset from the conductive gate by an amount defined by the first and second sidewall spacers (and thermal layer, if utilized). Next, a third sidewall spacer is formed adjacent to the second sidewall spacer, and a silicide is formed which is offset from the conductive gate by an amount defined by the third sidewall spacer. This method is presented with reference to FIGS. 6 through 9.

FIG. 1 illustrates a portion of a location 100 of a semiconductor device during a manufacturing process according to an embodiment of the present disclosure. At the manufacturing stage presented in FIG. 1, a substrate 10, conductive gate 15, and a first set of sidewall spacers 13 have been formed. Semiconductor substrate 10 can be a mono-crystalline silicon substrate. Alternatively, substrate 10 can also be a gallium arsenide substrate, a silicon-on-insulator substrate, a silicon on sapphire substrate, a semiconductor-on-insulator (SOI) substrate, or the like. Conductive gate 15 is typically a poly-crystalline or amorphous silicon having a typical critical dimension (CD) length (L) ranging from 300 to 1000 Angstroms (30 to 100 nm), and a typical height ranging from 1000 to 1500 Angstroms.

Sidewall spacers 13 will typically comprise an oxide or nitride comprising material. The width of the sidewall spacers 13 typically ranges from between 400 to 800 Angstroms, depending upon the desired location of the raised S/D, as seen in FIG. 2. Although sidewall spacers 13 are shown as being symmetric, sidewall spacers 13 may be asymmetric, depending upon device requirements. Various deposition and masking techniques are known which may be utilized with the teachings of the present disclosure to form sidewall spacers 13 into a desired configuration as regards symmetry and the location of raised S/D regions.

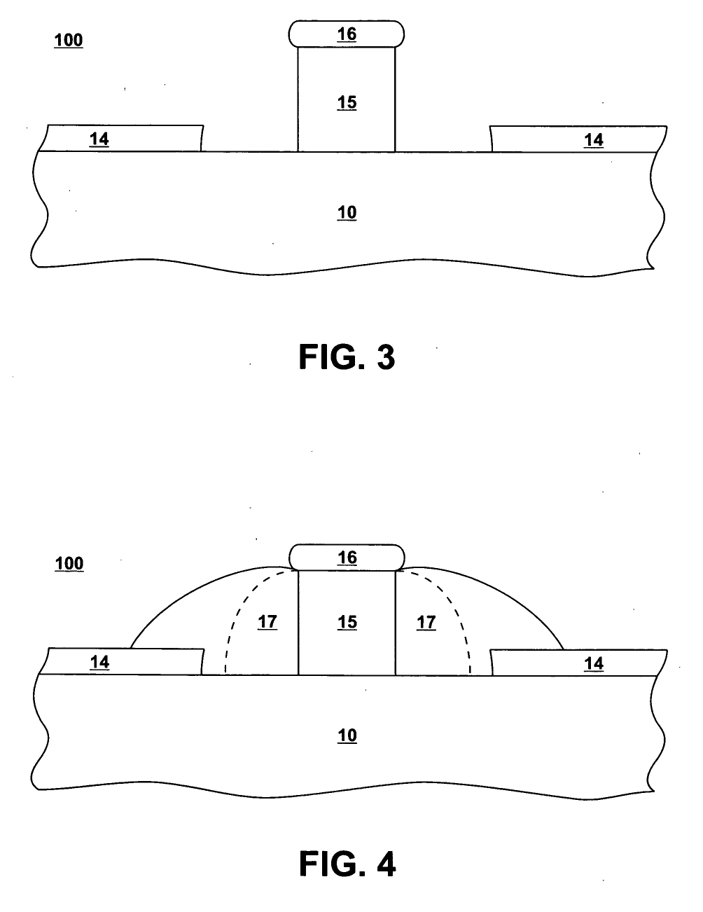

FIG. 2 illustrates location 100 following the formation of an epitaxial layer 14 overlying the substrate and adjacent to sidewall spacers 13, typically after a pre-cleaning process, and formation of an epitaxial layer 16 overlying the surface of the conductive gate 15. It should be noted that the epitaxial layer 16 is optional, that is, in embodiments where no epitaxial layer is desired overlying the surface of the gate structure, a mask, e.g., an ARC or BARC may be utilized to prevent the formation of an epitaxial layer overlying the gate structure. The thickness of the epitaxial layer 14 typically ranges from 100 to 300 Angstroms, depending upon device requirements and/or a desired thickness. The epitaxial layer 14 will serve as a raised S/D region for the location 100. After the SEG process to form epitaxial layer 14, location 100 will undergo an etch process to remove sidewall spacers 13, as seen in FIG. 3.

FIG. 3 illustrates location 100 following removal of sidewall spacers 13. Etch chemistries and techniques suitable to selectively etch the sidewall spacers are dependent upon the material composition of the spacers 13. For example, in embodiments where spacers 13 are a nitride, a wet etch utilizing hot phosphoric acid may be utilized. If spacers 13 are an oxide, an anisotropic dry etch process utilizing SF6 may be used.

FIG. 4 shows location 100 following a deposition and etch process to form second sidewall spacers 17 overlying a portion of the epitaxial layer 14. Sidewall spacers 17 will serve to define the deep S/D edge in a subsequent implantation process. As before, the material composition of sidewall spacers 17 may comprise an oxide material, a polysilicon, or a nitride material such as silicon nitride. The symmetric spacers shown in FIG. 4 are not the only possible outcome of the methodology of the present disclosure. For example, the dotted lines shown within sidewall spacers 17 represent the range of other possible spacer widths which can vary or be asymmetric. In an embodiment, the width of the second sidewall spacer 17 can be greater than the width of the first sidewall spacer (item 13, FIG. 1). In another embodiment, the width of the second sidewall spacer 17 can be less than the width of the first sidewall spacer. As before, device requirements will drive the configuration of sidewall spacers 17 with regard to symmetry and width. Following formation of sidewall spacers 17, an implantation process to form deep source/drain regions is conducted.

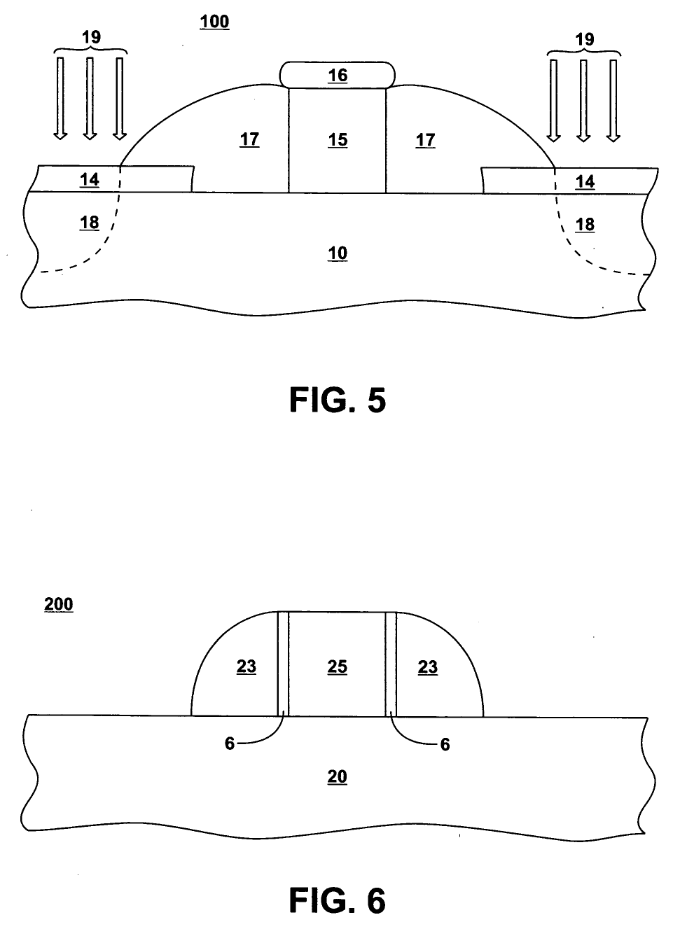

FIG. 5 illustrates a cross-sectional view of location 100 undergoing an implantation process 19 to form deep S/D regions 18 within the substrate 10. As seen in FIG. 5, the deep S/D regions 18 are offset from the gate structure 15 by an amount defined by the outer edges of the second sidewall spacers 17. Thus by varying the width and/or symmetry of sidewall spacers 17, a process engineer can readily offset the locations of the S/D regions 18 from the edges of the gate structure 15 and the edge of the epitaxial layer 14 to meet a particular design criteria or device technology requirement. The independent placement of the S/D 18 edge and the epitaxial layer 14 can be used to control series resistance and dopant gradient and depth. De-convolving these device controls adds more flexibility in tuning the transistor for a desired performance level.

FIGS. 6 through 9 illustrate cross-sectional views of a location 200 undergoing semiconductor device manufacturing process steps according to an embodiment of the present disclosure. In FIG. 6, a portion of a location 200 is shown after undergoing photolithography, deposition, and etch processes to form a conductive gate 25 overlying a substrate 20, first gate sidewall spacer 6, and a second sidewall spacer 23 adjacent to the conductive gate 25. Semiconductor substrate 20 can be a mono-crystalline silicon substrate. Alternatively, substrate 20 can also be a gallium arsenide substrate, a silicon-on-insulator substrate, a silicon on sapphire substrate, a semiconductor-on-insulator (SOI) substrate, or the like. Conductive gate 25 is preferably a poly-crystalline or amorphous silicon having a typical critical dimension length ranging from 300 to 1000 Angstroms, and a typical height ranging from 1000 to 1500 Angstroms.

Sidewall spacers 23 are formed immediately adjacent to the first sidewall spacer 6, and comprise a nitride or other suitable material, such as an oxide. Spacers 23 may range in width from 300 to 800 Angstroms. Sidewall spacer 6 may comprise an oxide material or a nitride material, and ranges in width from 100 to 250 Angstroms.

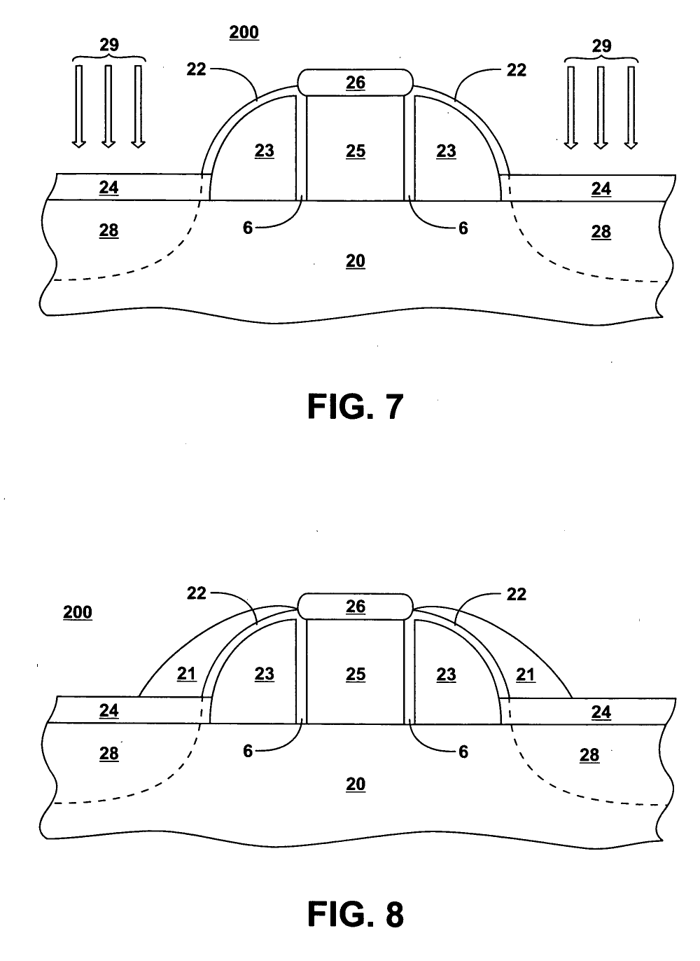

FIG. 7 illustrates a cross sectional view of location 200 following a pre-clean and the formation of an epitaxial layer 24 overlying a region of the substrate 20 adjacent to the second sidewall spacer 23, and formation of an optional epitaxial layer 26 overlying the top surface of the conductive gate 25. The thickness of the epitaxial layer 24 typically ranges from 100 to 300 Angstroms, depending upon device requirements and/or a desired thickness. The epitaxial layer 24 will serve as a raised S/D region for the device formed at location 200. After the SEG process to form epitaxial layer 24, location 200 undergoes an implantation process 29 to form deep S/D regions 28. The deep S/D regions 28 are offset from the conductive gate 25 by an amount defined by the first sidewall spacer 6 and the second sidewall spacer 23. Following the implantation process 29, a thermal oxidation process to form a thermal oxide layer 22 overlying the second sidewall spacer 23 may be performed. Alternately, the implantation process 29 may follow the thermal oxidation process to form oxide layer 22, as illustrated in FIG. 7.

After implantation 29, third sidewall spacer 21 is formed adjacent to the second sidewall spacer 23. The third sidewall spacer 21 may comprise a nitride material or an oxide material. Spacers 21 range in width from 200 to 400 Angstroms, depending upon the amount of offset desired from the edge of a subsequently formed silicide layer (FIG. 9) from the edges of conductive gate structure 25.

FIG. 9 illustrates location 200 after formation of a silicide layer 30 and a silicide cap 31. Silicide layer 30 is offset from the gate structure 25 by an amount defined by the third sidewall spacer 21. The advantage of offsetting the silicide layer 30 from the gate structure 25 is that a process engineer can employ these offsets separately to meet a device technology requirement or particular design criteria. Independent placement of the S/D 28 edge and the silicide layer 30 permits the process engineer to control series resistance and dopant gradient and depth, thus increasing flexibility in tuning the transistor for a desired performance level. Again, it should be noted that although spacers 23 and 21 are shown as being symmetric in FIGS. 6 through 9, numerous other combinations of varying widths are possible. Hence, utilizing the teachings of the present disclosure, it is possible to control the offset of the implant regions of the deep S/D 28 and the offset of the silicide layer 30 independently. Location 200 is now ready to undergo further manufacturing steps toward device completion.

Application of the methods as taught herein offers the advantage of permitting variable integration schemes that is suitable for the production of both NFET and PFET devices. For example, utilizing the disclosed methods, one may vary the placement of the silicide for an NFET device closer to the gate edge than would be the case for a PFET device, for which further placement of the silicide from the gate edge is desirable, due to the dopant gradient and concentration in each regime.

Generally, the NFET has a higher dopant concentration in the S/D and extension regions. The n-type dopant, e.g., arsenic, does not diffuse to the degree that the p-type dopant, e.g., boron does, thus the n-type junctions are more abrupt. This abrupt junction means that the silicide may be moved closer to the poly gate on the NFET and still maintain a good silicide-to-silicon contact resistance. However, if the silicide is moved too close to the poly gate on a PFET region, the silicide may be into a region that has lower dopant concentration due to diffusion, and the silicide-to-silicon resistance will increase, degrading device performance. The present disclosure thus enables greater flexibility for a process engineer to tailor the location of the silicide device in order to optimize performance.

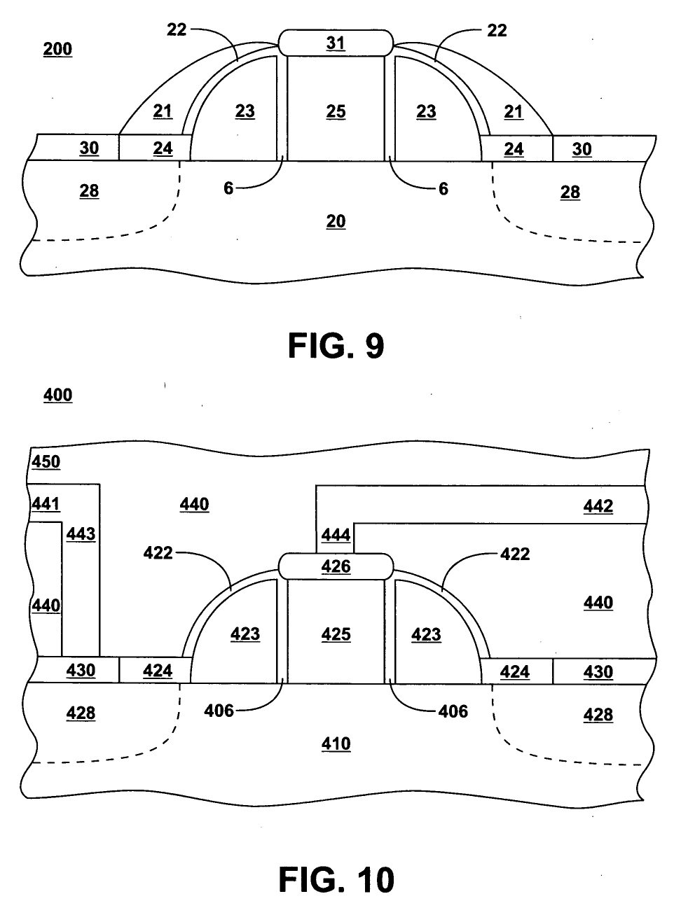

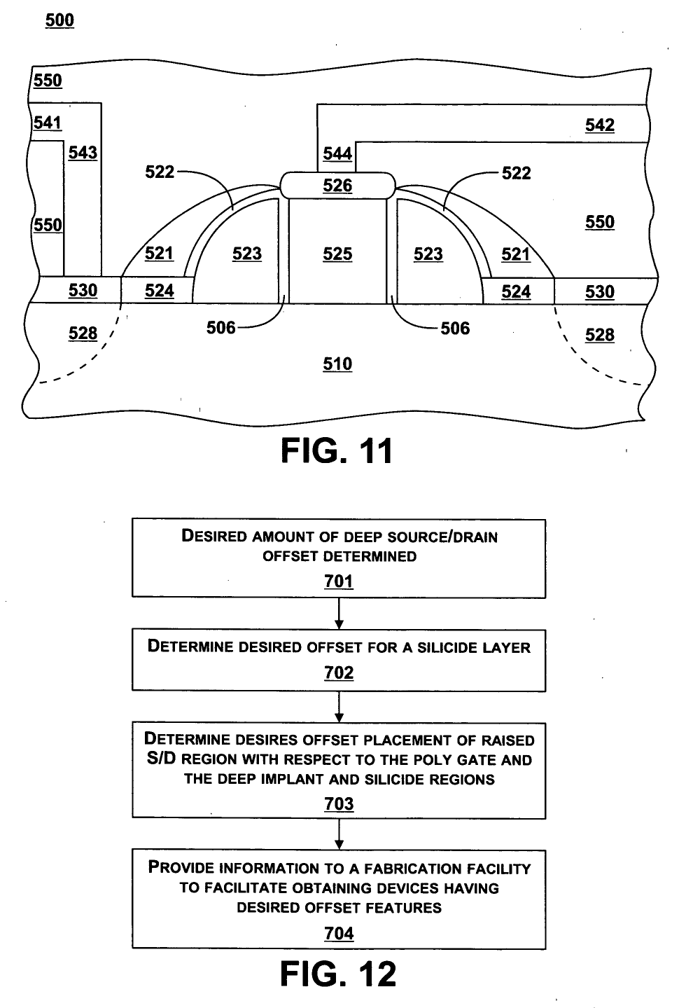

FIGS. 10 and 11 illustrates cross-sectional views of a portion 400 and a portion 500 respectively of a semiconductor device manufactured according to embodiments of the present disclosure. FIGS. 10 and 11 are simplified diagrams which do not show all of the features of portion 400 and portion 500 in order to keep the illustration from being cluttered.

In FIG. 10, other features illustrated include interconnects 441 and 442 connected to vias/contacts 443 and 444 within an interconnect dielectric region 440. A passivation layer 450 has been formed overlying portion 400. The conductive gate structure 425 may include a gate stack comprising a dielectric layer (not shown), in addition to the epitaxial layer 426, which may be a silicide. In FIG. 10, deep source drain regions 428 in the substrate 410, along with silicided epitaxial layer 430 and non-silicided epitaxial layer 424 are shown integrated into a transistor. In FIG. 10, one of the plurality of spacers utilized to form the offset features, e.g., deep S/D 428 or silicide layer 430 has been removed during subsequent fabrication of the device at location 400.

In FIG. 11, other illustrated features consist of interconnects 541 and 542 connected to vias/contacts 543 and 544 within an interconnect dielectric region 540. As with the manufacturing process of FIG. 10, a passivation layer 550 has been formed overlying portion 500, and the conductive gate structure 525 may include a gate stack comprising a dielectric layer (not shown), in addition to the epitaxial layer 526.

In FIG. 11, deep source drain regions 528 in the substrate 510, along with silicided epitaxial layer 530 and non-silicided epitaxial layer 524 are shown integrated into a transistor. The principle differences between the illustrations of FIG. 10 and FIG. 11 are that the second spacer 423 served to define the offset of the edge of the deep S/D region 428 in portion 400, while the third spacer 521 served to define the offset of the edge of the deep S/D region 528 in portion 500. The flexibility provided by the present disclosure permits independent control in the placement of deep S/D regions 428 and 528 and silicide regions 430 and 530 with respect to the gate structure 425 and 525.

FIG. 12 is a flow diagram of a method for forming a semiconductor device according to the present disclosure. At step 701, a determination is made as to the desired amount of offset for a deep source/drain implant from a gate structure. At step 702, a determination of a desired offset for a silicide layer from the deep S/D region is made. At step 703 a determination of a desired offset placement of the raised S/D region with respect to the poly gate and the deep implant and silicide regions is made. These determinations are part of an integration scheme to consider a plurality of sidewall spacers with spacer widths and implantation intervals integrated into a process line to produce a desired outcome. At step 704, information is provided to a manufacturing facility to obtain devices based on the results of these determinations.

It will be appreciated that the above disclosure can be implemented using a variety of techniques. For example, it will be appreciated that any number of substrate preclean steps can occur before the formation of any epitaxial layer. For example, U.S. patent application having Ser. No. 10/791,346, which is hereby incorporated in its entirety by reference, discloses several substrate preclean techniques appropriate for cleaning a substrate prior to forming an epitaxial layer.

In one example, contaminates on the surface of a substrate are subjected to a cleaning process comprising applying a plasma to a surface of the active regions produce a reduction reaction with the contaminates in an upper portion of the surface of the active regions. In an embodiment, the plasma comprises H₂. While the plasma is being applied to the upper portion of the exposed active regions, the resultant products or vapor byproducts of the reduction reaction are removed by the normal vacuum process within the chamber. Therefore, contaminates contained in the vapor byproducts and are vented away, leaving the upper portion of the surface of the active regions suitably clean for the ensuing epitaxial process. In one embodiment, the plasma process parameters comprise a gas flow of 450 sccm H2 and 300 sccm argon, at a chamber temperature of 400 degrees Celsius, with an high frequency (HF) power setting of 700 W, and a low frequency (LF) power setting of between approximately 50 to 100 W. Chamber pressure is 1 Torr, and the spacing between the surface of the active region and the faceplate of the tool (not shown) should be 300 mils. In other embodiments, plasma process parameters comprise a gas flow ranging from between 100-800 sccm H₂ and from between 100 and 600 sccm argon. Chamber temperatures can range between 300 to 450 degrees Celsius, and HF power settings from between 400-900 W, with LF power settings varying from between 0-150 W. Chamber pressures can range from between 1 mT-5 Torr, with spacing between the surface of the active region and the faceplate of the tool varying from between 200 to 400 mils. Exposure times for the various embodiments utilizing plasma range from between approximately 10 seconds up to approximately 120 seconds.

Various tool types are suitable for this cleaning, for example, CVD (Chemical Vapor Deposition) equipment, HDP (High Density Plasma) tools, etch chambers, or the like. Differences in chamber design, power settings, and species, e.g., H₂ with or H₂ without helium or nitrogen, will result in different thickness of the layer after anneal. Typically the layer after anneal will be between 20 and 50 Angstroms thick. This plasma cleaning process also results in passivation of Si—H bonds in the layer after anneal. No wet cleaning dip with hydrofluoric (HF) acid prior to SEG is necessary.

In addition to no longer requiring an HF dip prior to SEG, the reduced temperature of this H₂ plasma cleaning treatment results in a reduction of the SEG process thermal budget of more than 100 degrees Celsius. Typically pre-SEG cleaning processes are conducted at approximately 900 degrees Celsius or greater. In an embodiment of the present disclosure, the cleaning process occurs at less than approximately 800 degrees Celsius. In another embodiment, the cleaning process occurs at less than approximately 500 degrees Celsius or less. In addition, the cleaning processes of the present disclosure could be conducted at less than approximately 700 degrees Celsius or less, or even at less than approximately 600 degrees Celsius or less.

In another embodiment, location including includes a gate structure and active regions is subjected to a cleaning process utilizing a low-power dry etch to selectively remove an upper atomic layer of material from the active regions. The thickness of the upper atomic layer of material to be removed ranges from between 20 to about 50 Angstroms. In one embodiment, the dry etch process is an anisotropic dry etch utilizing a carbon-free gas as an etchant gas. In another embodiment, the anisotropic dry etch utilizes an oxygen- and carbon-free gas as an etchant gas. The etchant gas can comprise HBr, NF₃, SF₆, gaseous fluorine-interhalogenics such as ClF₃, or any gas containing fluorine, suitable to disassociate F-radicals, which does not contain oxygen and carbon. Prior to undergoing the anisotropic dry etch process, location 200 is subjected to a standard wet etch chemistry process utilizing a dilute HF solution (100:1) at room temperature, e.g., 20 to 26 degrees Celsius, for a time period ranging from 50 to 200 seconds. Following the HF clean, a low-power dry etch utilizing a temperature of approximately 400 degrees Celsius, RF power of approximately 375 W, pressure of approximately 150 mTorr, and a gas flow rate ranging from 50 to 100 sccm, is conducted. In other embodiments, the low-power dry etch utilizes a temperature ranging from between 300-500 degrees Celsius, with RF power ranging from between 200-700 W, a pressure ranging between 0-1 Torr, and a gas flow rate ranging from between 10-300 sccm, for a time ranging between 10 to 60 seconds.

This low-power dry etch removes carbon and oxygen contamination, and provides a very clean surface for SEG. The low temperature HF clean followed by the low-power dry etch does not require a high temperature bake. This results in a reduction of thermal budget for SEG of more than 100 degrees Celsius.

In another embodiment, a cleaning process is used that forms an oxidation layer of between 20 to 50 Angstroms on an upper surface of the active regions using a plasma to produce the oxidation layer on doped active regions. In an embodiment, the plasma is an O₂ plasma. In another embodiment, the plasma is an O₃ plasma.

An O₂ plasma production utilizes O₂ gas at a flow rate of 400 sccm, a pressure of 5 Torr, an HF of 300 W, an LF of 100 W, and a temperature of 400 degrees Celsius, with the time ranging from between about 10 to about 120 seconds. The spacing between the surface of the active regions and the faceplate of the vapor deposition apparatus (not shown) should be 400 mils. In other embodiments, the plasma production utilizes O₂ gas at a flow rate of between 100 and 1000 sccm, a pressure ranging from between 2-10 Torr, an HF ranging between 200-500 W, an LF ranging between 50-200 W, a temperature ranging between 300-450 degrees Celsius, for a time ranging from between approximately 10 to approximately 120 seconds. In an embodiment, the spacing between the surface of the active regions and the faceplate of the vapor deposition apparatus ranges from between 200 and 600 mils. The tool type used to generate the plasma could be CVD equipment, HDP tools, or etch chambers. In an embodiment where the plasma is O₃, plasma production utilizes O₃ gas at a flow rate of 300 sccm, a pressure of 5 Torr, an HF of 300 W, an LF of 100 W, and a temperature of 400 degrees Celsius for a time period ranging from between 10 to 120 seconds. The spacing between the surface of the active regions and the faceplate of the vapor deposition apparatus (not shown) should be 400 mils. In other embodiments, plasma production utilizes O₃ gas at a flow rate of between 50 and 600 sccm, a pressure ranging from between 2-10 Torr, an HF ranging between 200-500 W, an LF ranging between 50-200 W, and a temperature ranging from between 300-450 degrees Celsius for a time period ranging from between about 10 to about 120 seconds. In an embodiment, the spacing between the surface of the active regions and the faceplate of the vapor deposition apparatus ranges from between 200 and 600 mils. As was the case with the O₂ plasma, the tool type used to generate the plasma could be HDP tools, CVD equipment, or etch chambers.

Forming the oxidation layer facilitates trapping or fixing contamination in the oxide layer overlying the upper layer of the doped active regions for subsequent removal using a wet chemistry process. The wet etch chemistry process utilizes a dilute HF acid solution of 100:1 at room temperature, e.g. 20 to 26 degrees Celsius, for a time ranging from 50 to 200 seconds. Differences in chamber design, power settings and species employed, e.g., O₂ or O₃, results in differing thickness of the oxidation layer, hence the wide range in times for the HF dip. The use of an O₂ or O₃ plasma to create a contamination-trapping oxidation layer for removal by a room temperature HF dip results in a reduction of the thermal input for location 300.

Another possible pre-clean for use prior to formation of an SEG is disclosed in U.S. patent application having Ser. No. ______, (Attorney Docket Number 1458-H1962 Concurrently herewith) which is hereby incorporated in its entirety by reference, discloses another substrate preclean technique that facilitates a reduced temperature H₂ bake is performed following formation of any desired spacers, which can comprise one or more nitride or oxide layers and prior to SEG formation. This pre-clean and comprises a first pre-rinse with deionized water, followed by an oxide etch utilizing an aqueous solution of deionized water and hydrofluoric acid (HF or hydrogen fluoride in water) aqueous solution of approximately 30:1 (volumetric ratio) at 21 degrees Celsius, for a time period ranging from between 50-60 seconds. The weight percentage of HF recommended for the HF aqueous solution is 49% in a balance of deionized water (H₂O). Bulk HF aqueous solution can be purchased from various chemical suppliers in the HF weight percent range of 10% to 49%. In semiconductor fabrication facilities, this aqueous HF aqueous solution is typically diluted in the range 10:1 to 200:1. A 10:1 HF is 1 part aqueous HF (at 49% weight percent) and 10 parts H₂O. It will be appreciated that the etch rate of the HF aqueous solution is substantially linear with respect to both the concentration of the HF aqueous solution and the etch time. Therefore, various combinations of HF concentrations and etch times can be used to accomplish the oxide etch. Additionally, the temperature may vary.

After the HF etch, an overflow rinse utilizing deionized water is performed for a period ranging from approximately 120 to 600 seconds with a typical rinse being about 400 seconds. The cleaning process of portion 100 results in etching away of the surface contamination/debris located on substrate 10 resulting from offset spacer formation and/or dopant implantation. The upper semiconductor surface, i.e. silicon surface, of substrate 10 is also slightly etched, for example, from one to several mono layers of silicon, during the HF etch.

It should be noted that the amount of material removed during the HF etch is dependent upon the type of material being removed. For example, when native oxide is present, the HF etch will remove approximately 20 to 30 Angstroms of oxide. If a deposited oxide layer is present in addition to a native oxide, an over-etch of approximately 30% is generally desirable. For example, if removal of 100 Angstroms of a chemical vapor deposition (CVD) oxide is desired, the HF etch could be employed to remove approximately 120 to 130 Angstroms oxide removal. This latter example would be applicable in applications where a liner oxide of approximately 100 Angstroms thickness is employed between a conductive gate 25 and a nitride spacer.

The next steps in the cleaning process comprise a second pre-rinse with deionized water of approximately 30 seconds duration precedes the performance of a Standard Clean-1 (SC-1), a quick dry rinse (QDR), and a Standard Clean-2 (SC-2). The SC-1 and SC-2 components are followed by a second QDR, and an HF: H₂O etch, a third rinse, and an isopropyl alcohol (IPA) dry. The amount of material removed by the SC-1 and SC-2 components are implemented such that they etch from approximately one monolayer of silicon to approximately 10 to 100 Angstroms of silicon.

In an embodiment, the SC-1 utilizes an aqueous solution of ammonium hydroxide: hydrogen peroxide: deionized water at a ratio of approximately 1:1-4:6-40, at a temperature of approximately 60 degrees Celsius for approximately 72 minutes, to etch approximately 100 Angstroms of silicon. Synonyms for ammonium hydroxide (NH₄OH) include ammonia solution (typically contains between 12% and 44% ammonia before dilution), dilute ammonia, or concentrated ammonia. A first quick dry rinse is conducted for approximately 3 minutes. In an embodiment, the SC-2 utilizes a solution of hydrochloric acid: hydrogen peroxide: deionized water at an initial ratio of approximately 1:1:50 at a temperature of approximately 60 degrees for about 5 minutes. A second quick dry rinse is then conducted. Synonyms for hydrochloric acid (HCl) are hydrogen chloride, anhydrous hydrogen chloride, aqueous hydrogen chloride, chlorohydric acid, spirit of salts, and muriatic acid.

In a particular embodiment, the SC-1 utilizes a solution of ammonium hydroxide: hydrogen peroxide: deionized water at a ratio of approximately 1:4:20 at a temperature ranging of approximately 60 degrees Celsius for approximately 72 minutes. The SC-1 is the step in the clean sequence that etches the silicon. This occurs because the H₂O₂ (the oxidizer) becomes depleted in the solution with increasing time and increasing temperature. The methods of the present disclosure allow the initial concentration of hydrogen peroxide to be depleted to facilitate etching of the upper-most semiconductor portion. Depletion of the H₂O₂ is greatly enhanced when the solution temperature rises above 80 degrees Celsius, which can lead to an etch that is difficult to control if not carefully monitored. The temperature range of the SC-1 is expected to be approximately 55 to 85 degrees Celsius, with the etch occurring in a shorter period of time at higher temperatures than at lower temperatures. It is expected that the SC-1 etching will be better controlled at temperatures in the range of 55-80 degrees Celsius and better still at temperatures in the range of 55-75 degrees Celsius. Generally, it is expected that the substrate will be exposed to the SC-1 etch process for longer that 60 minutes. When the oxidizer stops protecting the silicon surface, the ammonium hydroxide (NH₄OH) starts to etch the silicon. Thus, a small amount of silicon can be etched in a controlled manner. The SC-1 can be performed in a re-usable bath where the solution is re-circulated and heated to maintain the desired temperature.

The mechanism of silicon and SiO₂ etching by a NH₄OH/H₂O₂ solution occurs when the solution is allowed to be depleted of H₂O₂. An alkaline solution, such as NH4OH4 in our example, will attack silicon by water molecules, according to the reaction:
Si+2H₂O+2OH⁻→Si(OH)₂(O⁻)₂+2H₂↑
A passivation layer formed by the H₂O₂ prevents this attack by the NH₄OH. H₂O₂ decomposes in the course to form O₂ and H₂O.
H₂O₂−→H₂O+½O₂
When the concentration of H₂O₂ is below 3×10⁻³M, then silicon will begin to etch, because of the absence of the inhibition layer.

As indicated in the above equations, heat is given off as the H₂O₂ is depleted. If a bath is used that is not recharged with fresh solution all H₂O₂ will be depleted, thereby no longer releasing heat. Therefore, the temperature can be monitored on the low end to indicate when the solution should be refreshed, while the temperature on the high end is monitored to prevent unusually rapid decomposition of the H₂O₂, which can lead to a process that is difficult to control.

The first quick dry rinse is conducted for approximately 3 minutes. The subsequent SC-2 utilizes a solution of hydrochloric acid: hydrogen peroxide: deionized water at a ratio of approximately 1:1:50 at a temperature of approximately 60 degrees for about 5 minutes. A quick dry rinse with deionized water, followed by an IPA dry process, is performed following the SC-2.

The IPA dry process uses a heated IPA vapor at approximately 82 degrees Celsius. The IPA vapor is generated in a separate chamber with 100% N₂ bubbled through 100% IPA (heated to 82 degrees Celsius). The IPA condenses on the wafer, and the solution drips off the bottom of the wafer. The IPA vapor concentration is slowly diluted to 100% N₂ before the wafers are removed from the rinsing/drying tank.

Subsequent to the SC-1 and SC-2 processes, the substrate will be further recessed (etched) as a result of the cleaning process. Next, an HF:H2O etch can be conducted at an aqueous solution ratio of 200:1 for about 65 seconds, which typically results in approximately 30 Angstroms of oxide removal. The HF:H2O etch 8 is followed by a rinse with deionized water for approximately 10 minutes duration. The deionized water rinse is followed by an IPA dry as described in the preceding paragraph. At this time, the source/drain regions of the substrate are ready for ion implantation or selective epitaxial growth.

In a particular embodiment, the SC-1 process comprises a pre-rinse with deionized water of approximately 30 seconds duration. The pre-rinse is followed by a SC-1 solution at a ratio of approximately 1:1-4:6-40, which includes the subranges of 0.25:1:5, 0.5:1:5, 1:1:5, 1:1:6, 1:4:20, and 1:1:40, ammonium hydroxide: hydrogen peroxide: deionized water at a temperature of approximately 60 degrees Celsius for approximately 5 minutes. A quick dry rinse (QDR) is then performed for approximately 3 minutes.

Following the SC-1 cleaning process, an SC-2 cleaning process is performed. In an embodiment, the SC-2 cleaning process includes utilizing an aqueous solution of hydrochloric acid:hydrogen peroxide:deionized water at a ratio of approximately 1:1:50 at a temperature of approximately 60 degrees Celsius for approximately 5 minutes. A QDR is then performed, and portion 200 is ready for the third cleaning. The weight percent composition of the hydrochloric acid:hydrogen peroxide: deionized water is 29% (weight percent) hydrochloric acid and 30% (weight percent) hydrogen peroxide in a balance of deionized water.

After the SC-1 and SC-2, a third cleaning process comprising an approximate 30 second pre-rinse, an oxide etch, an overflow rinse and an IP dry is performed. The oxide etch is accomplished utilizing a solution of deionized water and hydrofluoric acid at a ratio of approximately 200:1 for a time period ranging from between 450-650 seconds. Following the HF etch, an overflow rinse is performed for approximately 10 minutes. A final isopropyl alcohol (IPA) dry is then performed. Approximately 120-140 Angstroms of the surface of substrate 20 is removed in this process. Portion 200 is ready to undergo selective epitaxial growth.

The above-described cleaning process has been found to facilitate formation of an epitaxial layer on a semiconductor surface, specifically silicon. Because various etch processes can etch N- and P-type regions at different rates, it can be useful to amorphize an upper-most surface of the source/drain regions prior to the above-described clean to reduce any preferential etch differences between substrate regions of differing dopant types.

For example, the above-described clean process can etch the N-type silicon preferentially, as compared to the P-type silicon, resulting in a quality difference of the SEG between the N and P regions after SEG processing. Etch rate differences between N- and P-type regions can allow for contaminates to remain in the lesser-etched region. For example, an etch process that does not etch P-type regions at the same rate as N-type regions can result in P-regions maintaining embedded carbon that is incorporated from previous process steps. Without appropriate etching of silicon in the P-type regions during the clean, the carbon will remain, and the SEG will grow inconsistently. A high bake temperature of 900° C. can be used to overcome this growth issue on P areas, however, as stated previously, high bake temperatures can be detrimental to the device in that it causes diffusion and deactivation of the dopants. Amorphizing the source/drain regions can reduce etch differences associated with the above-described cleaning process as well as other processes that are used to etch doped substrate regions, thereby improving the quality of both the N and P regions.

It has been observed that the selective etching may be P-type over N-type, or N-type over P-type depending on the solution temperature, flow rate of the aqueous ammonia, concentration of the aqueous ammonia, agitation, or illumination of light. By amorphizing the silicon in this manner to a pre-defined depth, it has been observed that unbiased etching to the depth of the amorphized silicon can be achieved.

In one embodiment, N- and P-type extensions formed in the source/drain regions are amorphized by being implanted with the Xe, at a dose of 2E14 and energy of 10 keV, to create an amorphous depth of 100 A.

In accordance with another embodiment, a spacer structure having an undercut can be used to reduce or inhibit facet formation during a selective epitaxial growth process. Such a process can allow for greater lateral uniformity of junction or silicide features during implantation or silicidation processes, and can be accomplished by using a spacer formed with a bi-layer of materials, e.g., a thin liner, such as portion 29 of FIG. 1, of one material underlying another layer of material from which the ‘main’ spacer is formed. The thin liner and other material layer are selected such that the two materials are selectively etchable with respect to the other, for example, a thin oxide liner and a nitride layer. By etching the underlying portion of the spacer, an undercut can be formed that reduces facets during epitaxial formation.

In another embodiment, a method of germanium-content engineering can be used during a selective epitaxial growth (SEG) process to form raised source drain regions, such that the germanium-content is engineered to facilitate subsequent cobalt-silicidation, or for nickel silicide processes. For example, U.S. patent application having Ser. No. 10/969,774 (Attorney Docket Number 1458-H1955), which is hereby incorporated in its entirety by reference, discloses such a technique.

The SEG formation process commences with a germanium content on the order of between approximately 3-5% to ensure good growth conditions at high growth rates for both N- and PMOS. The germanium content is reduced during growth of the upper portion of the SEG layer (raised source/drain region) to provide a good substrate for subsequent cobalt silicidation. Thus the raised source drain region comprises a first portion nearest the semiconductor substrate having a Ge content greater than a second portion of the raised source drain furthest from the substrate. Due to the reduction in germanium during growth of the upper portion of the SEG layer, the germanium-to-silicon ratio in the first portion closest the substrate will be different (typically greater than) from the germanium-to-silicon ratio in the uppermost portion of the SEG layer.

This method permits increased throughput for SEG at reduced thermal budget, as well as the ability to continue using cobalt rather than nickel for the silicide layer. Using a graded SEG as described allows for a self-limiting or self-stopping cobalt silicidation process, due to the higher conversion temperatures required to create cobalt-silicide in the presence of germanium. Utilizing the methods during the manufacture of CMOS devices results in reduced junction leakage. A reduction in junction leakage results in improved device performance.

In one embodiment, a dopant profile for a Ge-to-Si ratio where a portion of SEG 38 closest to an underlying substrate will typically have a Ge-to-Si ratio in the range from 15% to 35%. While the portion of SEG 38 furthest from the substrate 10 typically has a reduced Ge-to Si ratio in the range from 0% to 2.5%. Note that listed percentages are atomic percentages unless otherwise stated.

Following the formation of the Ge-gradient in the source/drain regions, a silicidation process is carried out to form a silicide layer overlying a portion of the raised source/drain region. In an embodiment, the silicide layer comprises cobalt disilicide (CoSi₂). In an embodiment, the cobalt disilicide is formed at a temperature ranging from 600 to 800 degrees Celsius. Formation of the cobalt disilicide further comprises depositing a cobalt metal, performing a first anneal at a temperature ranging from 450 to 550 degrees Celsius, performing a wet strip with a sulfuric peroxide mixture followed by a wet strip with an ammonium peroxide mixture, and performing a second anneal at a temperature ranging from 600 to 800 degrees Celsius.

In another embodiment, the silicide layer comprises nickel silicide (NiSi). In an embodiment, the nickel silicide is formed at a temperature ranging from 350 to 500 degrees Celsius. The nickel silicide is formed by depositing a nickel metal and performing an anneal at a temperature ranging from 350 to 500 degrees Celsius. Following the anneal, a wet strip with a sulfuric peroxide mixture is performed, followed by a wet strip with an ammonium peroxide mixture. It should be noted that more than one anneal may be utilized to form the nickel silicide, e.g., a two step anneal process such as a first anneal at a temperature ranging from 300 to 400 degrees Celsius following nickel metal deposition, performing the wet strips, then performing a second anneal at a temperature ranging from approximately 400 to 500 degrees Celsius.

The method and apparatus herein provides for a flexible implementation. Although described using certain specific examples, it will be apparent to those skilled in the art that the examples are illustrative, and that many variations exist. For example, the disclosure is discussed herein primarily with regard to independent control of the placement of a silicide and the amount of offset of a source/drain region from a gate structure for a CMOS device, however, the invention can be employed with other device technologies to create deep source/drain offsets and determine silicide location during device manufacture. Additionally, various types of deposition and etch devices are currently available which could be suitable for use in employing the method as taught herein. Note also, that although an embodiment of the present invention has been shown and described in detail herein, along with certain variants thereof, many other varied embodiments that incorporate the teachings of the invention may be easily constructed by those skilled in the art. Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims. Accordingly, the present invention is not intended to be limited to the specific form set forth herein, but on the contrary, it is intended to cover such alternatives, modifications, and equivalents, as can be reasonably included within the spirit and scope of the invention.

What is claimed is:

1. A method comprising:
forming a first sidewall spacer adjacent to a conductive gate overlying a substrate;
forming an epitaxial layer overlying the substrate adjacent to the first sidewall spacer;
forming a second sidewall spacer adjacent to the conductive gate and overlying a portion of the epitaxial layer; and
forming a deep source/drain region, wherein the deep source/drain region is offset from the conductive gate by an amount defined by the second sidewall spacer.

2. The method of claim 1, further comprising:
removing the first sidewall spacer prior to forming the second sidewall spacer.

3. The method of claim 2, wherein the width of the second sidewall spacer is greater than the width of the first sidewall spacer.

4. The method of claim 2, wherein the width of the second sidewall spacer is less than the width of the first sidewall spacer.

5. The method of claim 1, wherein the step of forming the epitaxial layer further comprises forming the epitaxial layer overlying the surface of the conductive gate.

6. A method of manufacturing a semiconductor device comprising:
forming a first sidewall spacer adjacent to a conductive gate overlying a substrate;
forming a second sidewall spacer overlying the first sidewall spacer and adjacent to the conductive gate;
forming an epitaxial layer overlying a region of the substrate adjacent to the second sidewall spacer;
forming a deep source/drain region, wherein the deep source/drain region is offset from the conductive gate by an amount defined by the first sidewall spacer and the second sidewall spacer;
forming a third sidewall spacer adjacent to the second sidewall spacer; and
forming a silicide offset from the conductive gate by an amount defined by the third sidewall spacer.

7. The method of claim 6, further comprising forming a thermal layer overlying the second sidewall spacer.

8. The method of claim 7, wherein the thickness of the thermal layer ranges from about 30 to 70 Angstroms.

9. The method of claim 6, wherein the step of forming the epitaxial layer further comprises forming the epitaxial layer overlying the surface of the gate.

10. The method of claim 6, wherein the width of the first sidewall spacer ranges from between 400 to 800 Angstroms.

11. The method of claim 6, wherein the first sidewall spacer comprises a material selectively etchable with respect to an immediately adjacent sidewall spacer material.

12. The method of claim 6, wherein the third sidewall spacer comprises a material selectively etchable with respect to an immediately adjacent sidewall spacer material.

13. The method of claim 6, wherein the second sidewall spacer comprises an oxide.

14. The method of claim 6, wherein the second sidewall spacer comprises a nitride.

15. A method for forming a semiconductor device comprising:
determining a desired offset for a deep source/drain region from a conductive gate;
determining a desired offset for a silicide layer from the deep source/drain region;
determining a desired offset for a raised source/drain region from a conductive gate and the deep source/drain region and the silicide layer; and
providing information to a semiconductor device fabrication facility to implement the desired offsets.

16. A semiconductor device comprising:
a transistor comprising a raised source/drain region and a sidewall spacer, wherein the raised source/drain region is immediately adjacent to the sidewall spacer and offset from a conductive gate by an amount defined by the sidewall spacer, and wherein at least a portion of the raised source/drain region includes a silicide layer offset from the conductive gate by an amount defined by a second sidewall spacer; and
a deep source/drain implant offset from the conductive gate by an amount defined by a third sidewall spacer.

17. The semiconductor device of claim 16, wherein the silicide layer offset ranges from 300 to 900 Angstroms.

18. The semiconductor device of claim 16, wherein the deep source/drain implant offset ranges from 300 to 900 Angstroms.
